(19) United States
(12) Patent Application Publication
(10) Pub. No.: US 2025/0336850 A1
(43) Pub. Date: Oct. 30, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Hiroshi OKUMURA, Kyoto-shi (JP)

(21) Appl. No.: 19/186,029

(22) Filed: Apr. 22, 2025

(30) Foreign Application Priority Data
Apr. 25, 2024 (JP) 2024-071216

(51) Int. Cl. H01L 23/00

(52) U.S. Cl. CPC H01L 24/02; H01L 24/03; H01L 24/05; H01L 24/13; H01L 24/04; H01L 24/11; H01L 24/14; H01L 2224/02317; H01L 2224/02331; H01L 2224/0235; H01L 2224/02373; H01L 2224/02381; H01L 2224/0345; H01L 2224/03462; H01L 2224/03614; H01L 2224/0362; H01L 2224/03622; H01L 2224/0401; H01L 2224/05008; H01L 2224/05011; H01L 2224/05015; H01L 2224/05022; H01L 2224/05027; H01L 2224/05082; H01L 2224/05147; H01L 2224/05166; H01L 2224/05555; H01L 2224/05572; H01L 2224/05647; H01L 2224/11849; H01L 2224/13006; H01L 2224/13014; H01L 2224/13024; H01L 2224/1413; H01L 2924/30101

(57) ABSTRACT

A semiconductor device includes a semiconductor element, an electrode located on a first side in a thickness direction of the semiconductor element, a re-wiring located on the first side in the thickness direction with respect to the electrode and electrically connected to the electrode, and a terminal located on the first side in the thickness direction with respect to the re-wiring and electrically connected to the re-wiring. The re-wiring includes a first re-wiring and a second re-wiring. The dimension of the second re-wiring in the thickness direction is greater than the dimension of the first re-wiring in the thickness direction.

### FIELD

The present disclosure relates to a semiconductor device and a method for manufacturing a semiconductor device.

BACKGROUND

JP-A-2014-165335 discloses an example of a semiconductor device. The semiconductor device includes a substrate having an element forming surface, a pad terminal disposed on the element forming surface, a passivation film covering a portion of the pad terminal and the element forming surface, a Cu re-wiring extending from the pad terminal, an organic coating film covering the Cure-wiring, and a resin film covering the organic coating film. According to the publication, for the semiconductor device that passes a relatively large electric current through the Cu re-wiring, the resistance of the Cu re-wiring layer is reduced by increasing the area of the Cu re-wiring in plan view. As semiconductor devices are expected to carry larger electric currents, it may be desirable to further reduce the resistance of the Cure-wirings.

### DRAWINGS

FIG. 1 is a plan view of a semiconductor device according to a first embodiment of the present disclosure.

FIG. 2 is a plan view corresponding to FIG. 1, with the illustration of a plurality of terminals and a plurality of conductive layers omitted.

FIG. 3 is a plan view corresponding to FIG. 2, with the illustration of a second insulating film omitted.

FIG. 4 is a partially enlarged sectional view taken along line IV-IV in FIG. 1.

FIG. 5 is a partially enlarged sectional view taken along line V-V in FIG. 1.

FIG. 6 is a sectional view illustrating a step of a method for manufacturing a semiconductor device according to the first embodiment of the present disclosure.

FIG. 7 is a sectional view illustrating a step subsequent to FIG. 6.

FIG. 8 is a sectional view illustrating a step subsequent to FIG. 7.

FIG. 9 is a sectional view illustrating a step subsequent to FIG. 8.

FIG. 10 is a sectional view illustrating a step subsequent to FIG. 8.

FIG. 11 is a sectional view illustrating a step subsequent to FIG. 9.

FIG. 12 is a sectional view illustrating a step subsequent to FIG. 11.

FIG. 13 is a sectional view illustrating a step subsequent to FIG. 12.

FIG. 14 is a sectional view illustrating a step subsequent to FIG. 12.

FIG. 15 is a sectional view illustrating a step subsequent to FIG. 13.

FIG. 16 is a sectional view illustrating a step subsequent to FIG. 15.

FIG. 17 is a sectional view illustrating a step subsequent to FIG. 16.

FIG. 18 is a sectional view illustrating a step subsequent to FIG. 16.

FIG. 19 is a sectional view illustrating a step subsequent to FIG. 17.

FIG. 20 is a sectional view illustrating a step subsequent to FIG. 18.

FIG. 21 is a sectional view illustrating a step subsequent to FIG. 19.

FIG. 22 is a sectional view illustrating a step subsequent to FIG. 20.

FIG. 23 is a sectional view illustrating a step subsequent to FIG. 21.

FIG. 24 is a sectional view illustrating a step subsequent to FIG. 22.

FIG. 25 is a sectional view, similar to FIG. 4, of a semiconductor device according to a second embodiment of the present disclosure.

FIG. 26 is a sectional view, similar to FIG. 5, of the semiconductor device according to the second embodiment of the present disclosure.

FIG. 27 is a sectional view, similar to FIG. 4, of a semiconductor device according to a third embodiment of the present disclosure.

FIG. 28 is a sectional view, similar to FIG. 4, of a semiconductor device according to a fourth embodiment of the present disclosure.

FIG. 29 is a sectional view, similar to FIG. 5, of the semiconductor device according to the fourth embodiment of the present disclosure.

### EMBODIMENTS

The following specifically describes preferred embodiments of the present disclosure with reference to the drawings.

In the following description, the same or similar elements are indicated by the same reference numerals, and redundant descriptions are omitted. In the present disclosure, the terms such as “first”, “second”, “third”, and so on are used only as labels and not to imply any order of the items referred to by the terms.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, the expression “An object A contains (or the material of an object A includes) a material C” implies the situation where, unless otherwise specifically noted, “the object A is made of (or the material of the object A is) the material C” or “the object A is mainly made of (or the material of the object A is) the material C”. Still further, “A surface A faces in a direction B (or toward a first side or an opposite second side in the direction B) is not limited, unless otherwise specifically noted, to the situation where the surface A forms an angle of 90° with the direction B but includes the situation where the surface A is inclined relative to the direction B.

### First Embodiment

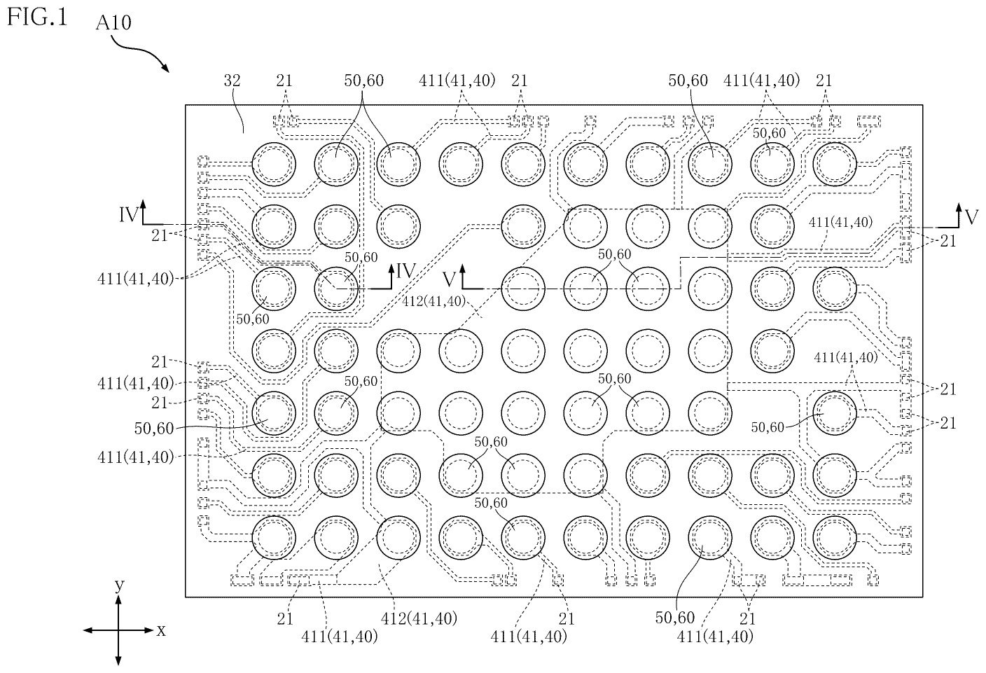

With reference to FIGS. 1 to 5, the following describes a semiconductor device A10 according to a first embodiment of the present disclosure. The semiconductor device A10 may be a large-scale integration (LSI) that uses what is called wafer-level chip size package (WL-CSP). The semiconductor device A10 includes a semiconductor element 10, a plurality of electrodes 21, a passivation film 22, a first insulating film 31, a second insulating film 32, a plurality of re-wiring 40, a plurality of terminals 50, and a plurality of conductive bonding layers 60.

For convenience of description, reference is made to a thickness direction z, a first direction x, and a second direction y, which are perpendicular to each other. The thickness direction z corresponds to the thickness direction of the semiconductor device A10. Additionally, “in plan view” refers to a view as seen in the thickness direction z. The first direction x is perpendicular to the thickness direction z. The second direction y is perpendicular to the thickness direction z and the first direction x. One side in the thickness direction z is referred to as the z1 side in the thickness direction z, and the other side as the z2 in the thickness direction z. The z1 side in the thickness direction z may be referred to as the upper side, and the z2 side as the lower side. Note, however, that the terms, such as “top”, “bottom”, “upper”, “lower”, “upper surface”, and “lower surface” are used to describe the relative positions of elements in the thickness direction z, and not necessarily describe their positions with respect to the direction of gravity.

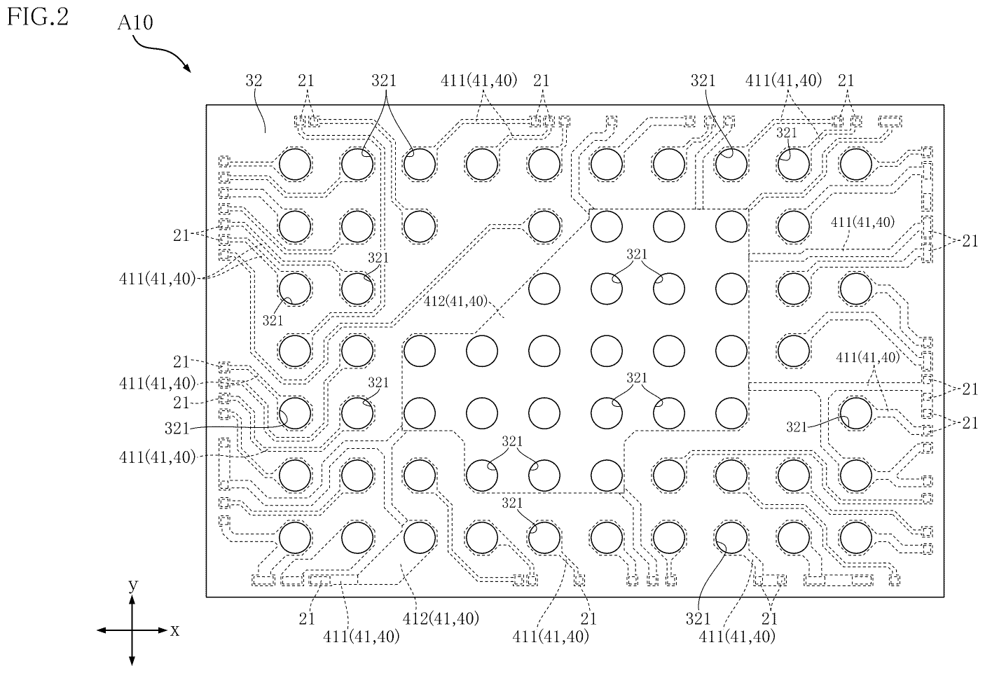

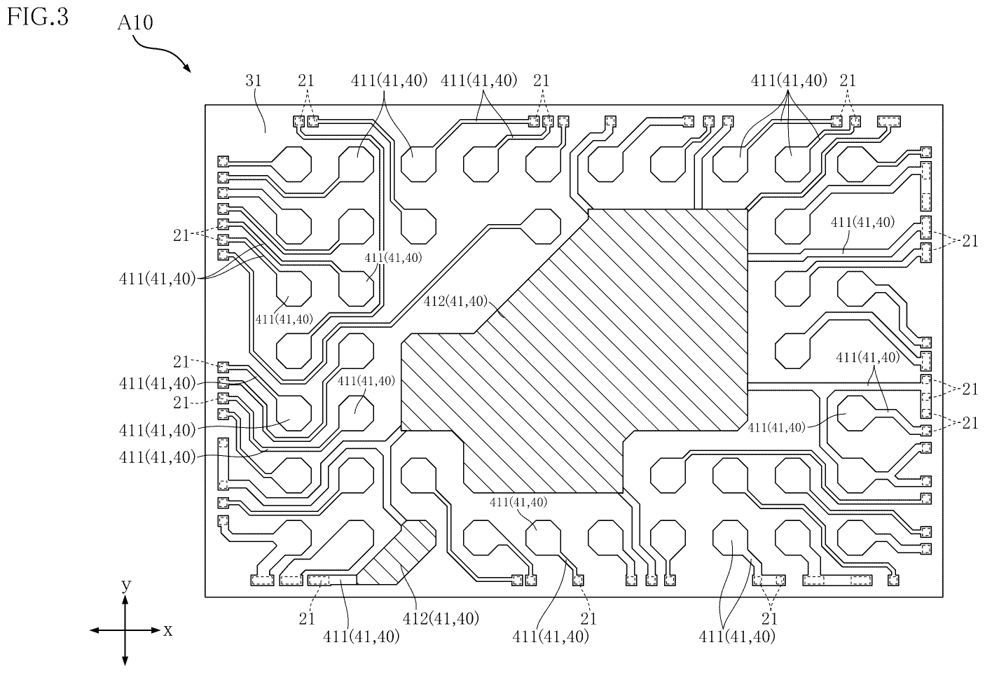

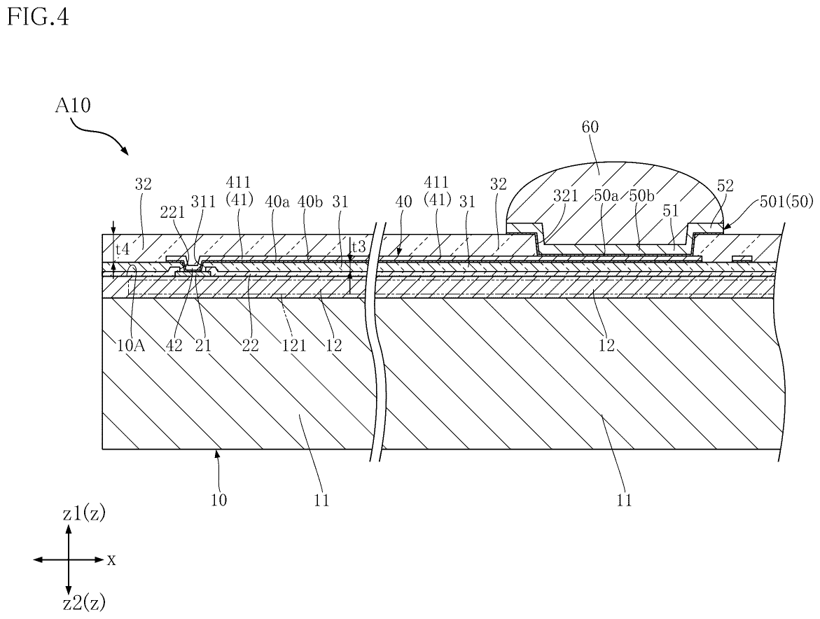

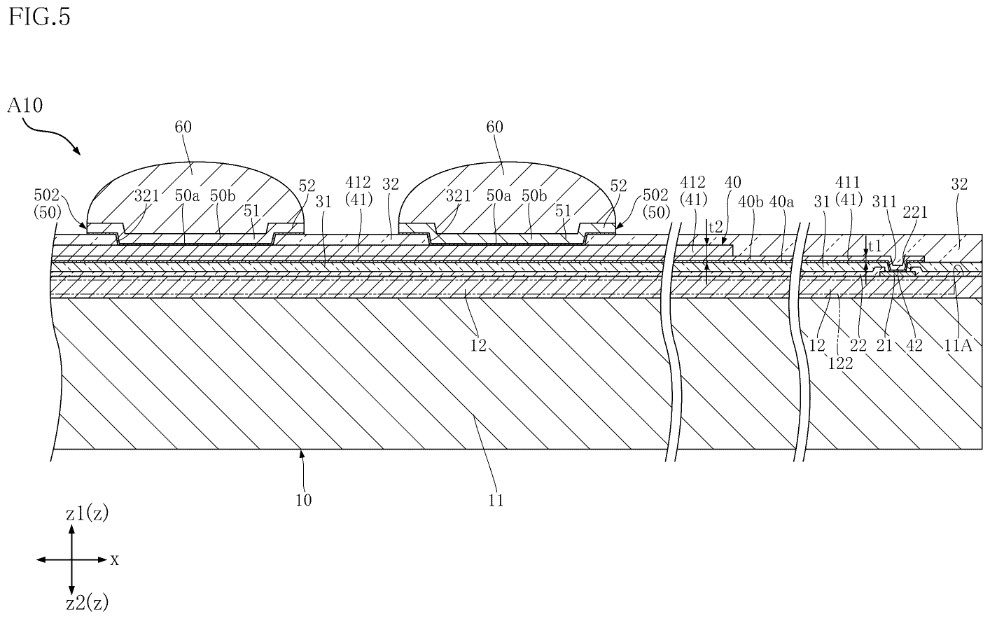

FIG. 1 is a plan view of the semiconductor device A10. FIG. 2 is a plan view of the semiconductor device A10, with the illustration of the terminals 50 and the conductive bonding layers 60 omitted. FIG. 3 is a plan view of the semiconductor device A10, with the illustration of the second insulating film 32 further omitted from FIG. 2. FIG. 4 is a partially enlarged sectional view taken along line IV-IV in FIG. 1. FIG. 5 is a partially enlarged sectional view taken along line V-V in FIG. 1.

As shown in FIGS. 4 and 5, the semiconductor element 10 includes a semiconductor substrate 11, and a semiconductor layer 12 located on the z1 side in the thickness direction z of the semiconductor substrate 11. The semiconductor element 10 has an obverse surface 10A facing the z1 side in the thickness direction z. The semiconductor layer 12 includes the obverse surface 10A. The semiconductor substrate 11 is formed from a silicon wafer, for example. Various semiconductor circuits, such as transistors and diodes, are formed on or near the obverse surface 10A of the semiconductor layer 12. In one example, the semiconductor layer 12 includes a first circuit 121 and a second circuit 122. The second circuit 122 may be a switching circuit, such as a metal-oxide-semiconductor field-effect transistor (MOSFET) or an insulated gate bipolar transistor (IGBT). The first circuit 121 is a control circuit for driving the second circuit 122. The second circuit 122 is driven by the first circuit 121. For example, the semiconductor element 10 is an LSI that includes the first circuit 121 and the second circuit 122 described above.

As shown in FIGS. 4 and 5, the electrodes 21 are located on the z1 side in the thickness direction z of the semiconductor element 10. The electrodes 21 are in contact with the obverse surface 10A (the surface facing the z1 side in the thickness direction z) of the semiconductor element 10. Each electrode 21 is electrically connected to a semiconductor circuit that is formed in the semiconductor layer 12. The electrodes 21 contain aluminum (Al), for example.

As shown in FIGS. 4 and 5, the passivation film 22 covers the obverse surface 10A of the semiconductor element 10 and a portion of each electrode 21. The passivation film 22 is a thin film containing silicon dioxide (SiO₂) or silicon nitride (Si₃N₄) or a stack of such thin films. The passivation film 22 has a plurality of openings 221. The openings 221 are each located above a corresponding electrode 21. The electrodes 21 are exposed through the respective openings 221 in the passivation film 22.

As shown in FIGS. 4 and 5, the first insulating film 31 is located between the semiconductor element 10 and the second insulating film 32 in the thickness direction z. The first insulating film 31 covers a portion of each electrode 21, and the passivation film 22. The first insulating film 31 is an insulator containing an organic compound. Examples of the organic compound include, but not limited to, polyimide. The first insulating film 31 includes portions located between the passivation film 22 and the re-wirings 40. As shown in FIGS. 4 and 5, the first insulating film 31 has a first opening(s) 311 extending through it in the thickness direction z. As viewed in the thickness direction z, the first opening 311 overlaps with one of the openings 221 in the passivation film 22. In the semiconductor device A10, the first opening 311 exposes one of the electrodes 21. In the illustrated example, the first opening 311 has an inclined inner surface relative to the thickness direction z. The cross-sectional area of the first opening 311 in a plane perpendicular to the thickness direction z gradually decreases from the z1 side to the z2 side in the thickness direction z.

As shown in FIGS. 4 and 5, the re-wirings 40 are located on the z1 side in the thickness direction z with respect to the electrodes 21. The re-wirings 40 are located between the plurality of electrodes 21 and the plurality of terminals 50 in the thickness direction z. Each re-wiring 40 is electrically connected to one of the electrodes 21.

Each re-wiring 40 includes a first base layer 40a and a first conductive layer 40b. The first base layer 40a includes a barrier layer in contact with one of the electrodes 21 and the first insulating film 31, and a seed layer stacked on the barrier layer. The barrier layer contains titanium (Ti). The seed layer contains copper (Cu). The first conductive layer 40b is stacked on the seed layer of the first base layer 40a. The first conductive layer 40b contains copper. The dimension of the first conductive layer 40b in the thickness direction z is greater than the dimension of the first base layer 40a in the thickness direction z.

As shown in FIGS. 4 and 5, each re-wiring 40 has a main portion 41 and a contact portion 42. The contact portion 42 is electrically connected to one of the electrodes 21. The contact portion 42 is in contact with the first insulating film 31 and is received within a first opening 311 in the first insulating film 31. As viewed in the thickness direction z, the entire contact portion 42 overlaps with one of the openings 221 in the passivation film 22. The main portion 41 is located on the opposite side of the contact portion 42 from the plurality of electrodes 21 in the thickness direction z. The contact portion 42 is connected to the main portion 41. The main portion 41 is located between the first insulating film 31 and the second insulating film 32.

As shown in FIGS. 3 to 5, the main portions 41 (the re-wirings 40) include a plurality of first re-wirings 411 and a second re-wiring 412. As shown in FIG. 5, the first re-wirings 411 and the second re-wiring 412 have different dimensions in the thickness direction z. The dimension t2 of the second re-wiring 412 in the thickness direction z is greater than the dimension t1 of the first re-wirings 411 in the thickness direction z. For example, the dimension t2 of the second re-wiring 412 in the thickness direction z is at least 150% of the dimension t1 of the first re-wirings 411 in the thickness direction z. The dimension t2 of the second re-wiring 412 in the thickness direction z is preferably at least 150% and at most 1000% of the dimension t1 of the first re-wirings 411 in the thickness direction z, and more preferably at least 150% and at most 300%. To give specific examples, the dimension t1 of the first re-wirings 411 in the thickness direction z is about 5 μm, and the dimension t2 of the second re-wiring 412 in the thickness direction z is about 8 to 15 μm. Note, however, that the dimensions t1 and t2 of the first re-wirings 411 and the second re-wiring 412 are not limited to these examples.

In the example shown in FIGS. 3 and 5, the second re-wiring 412 is connected to a plurality of first re-wirings 411. The first conductive layer 40b of the second re-wiring 412 is formed by depositing a greater amount of copper than that of each first re-wiring 411. In FIG. 3, the second re-wiring 412 is shown with hatching. In the semiconductor device A10, some of the plurality of re-wirings 40 are composed of both a first re-wiring 411 and the second re-wiring 412. The rest of the re-wirings 40 are composed solely of a first re-wiring 411 without the second re-wiring 412. In a different example not shown in the figures, the second re-wiring 412 is not connected to a first re-wiring 411. In other words, the re-wirings 40 of such an example include those composed solely of the second re-wiring 412, and the rest are composed solely of a first re-wiring 411.

As shown in FIGS. 1, 3, and 4, each first re-wiring 411 is electrically connected to the first circuit 121 of the semiconductor element 10 via an electrode 21. As shown in FIGS. 1, 3, and 5, the second re-wiring 412 is electrically connected to the second circuit 122 of the semiconductor element 10 via a first re-wiring 411 and an electrodes 21.

As shown in FIGS. 4 and 5, the second insulating film 32 is located on the z1 side in the thickness direction z with respect to the first insulating film 31. The second insulating film 32 covers the first insulating film 31 and the re-wirings 40. The second insulating film 32 is an insulator containing an organic compound. The second insulating film 32 contains polyimide, for example. In the semiconductor device A10, the second insulating film 32 has the same composition as the first insulating film 31. The second insulating film 32 may contain polyamide, polybenzoxazole, or phenol resin, instead of polyimide.

The second insulating film 32 is in contact with the terminals 50. As shown in FIG. 4, a dimension t4 of the second insulating film 32 in the thickness direction z is greater than a dimension t3 of the first insulating film 31 in the thickness direction z. The second insulating film 32 has a second opening(s) 321 extending through it in the thickness direction z. The second opening 321 exposes the main portion 41 of one of the re-wirings 40. The second opening 321 receives a portion of one of the terminals 50. In the illustrated example, the second opening 321 has an inclined inner surface relative to the thickness direction z. The cross-sectional area of the second opening 321 in a plane perpendicular to the thickness direction z gradually decreases from the z1 side to the z2 side in the thickness direction z.

As shown in FIGS. 4 and 5, the terminals 50 are located on the opposite side of the semiconductor element 10 in the thickness direction z with respect to the electrodes 21 and the re-wirings 40. Each terminal 50 is electrically connected to the main portion 41 (the first re-wiring 411 or the second re-wiring 412) of one of the re-wirings 40. Thus, each terminal 50 is electrically connected to one of the electrodes 21. Each terminal 50 is located on the z1 side in the thickness direction z with respect to the re-wiring 40 that is connected to the terminal 50. In the semiconductor device A10, the terminals 50 are appropriately aligned along the first direction x and the second direction y as viewed in the thickness direction z as shown in FIG. 1.

Each terminal 50 includes a second base layer 50a and a second conductive layer 50b. The second base layer 50a includes a barrier layer in contact with a corresponding re-wiring 40 (its main portion 41) and the second insulating film 32, and a seed layer stacked on the barrier layer. The barrier layer contains titanium, and the seed layer contains copper. The second conductive layer 50b is stacked on the seed layer of the second base layer 50a. The second conductive layer 50b contains copper. The dimension of the second conductive layer 50b in the thickness direction z is greater than the dimension of the second base layer 50a in the thickness direction z.

As shown in FIGS. 4 and 5, each terminal 50 includes a first portion 51 and a second portion 52. The first portion 51 is received within a second opening 321 in the second insulating film 32. The second portion 52 is connected to the first portion 51 and protrudes beyond the second opening 321. As viewed in thickness direction z, the second portion 52 extends outside beyond the second opening 321.

The plurality of terminals 50 include a plurality of first terminals 501 and a plurality of second terminals 502. As shown in FIG. 4, each first terminal 501 is electrically connected to a first re-wiring 411. Each first terminal 501 is electrically connected to the first circuit 121 of the semiconductor element 10 via a first re-wiring 411 and an electrode 21. As shown in FIG. 5, each second terminal 502 is electrically connected to the second re-wiring 412. Each second terminal 502 is electrically connected to the second circuit 122 of the semiconductor element 10 via the second re-wiring 412, a first re-wiring 411, and an electrode 21. As shown in FIGS. 1 and 5, in the present embodiment, the plurality of second terminals 502 are connected to the second re-wiring 412.

As shown in FIGS. 4 and 5, the conductive bonding layers 60 are located on the z1 side in the thickness direction z with respect to the plurality of terminals 50. The conductive bonding layers 60 are each electrically connected to a corresponding terminal 50. The conductive bonding layers 60 contain metal. The conductive bonding layers 60 is solder, for example. The composition of the conductive bonding layers 60 includes tin (Sn), for example. The melting point of the conductive bonding layers 60 is lower than that of the terminals 50. The upper surface (the surface facing in the z1 side in the thickness direction z) of each conductive bonding layer 60 is curved. Note, however, that the shape of the conductive bonding layers 60 is not limited to the illustrated example.

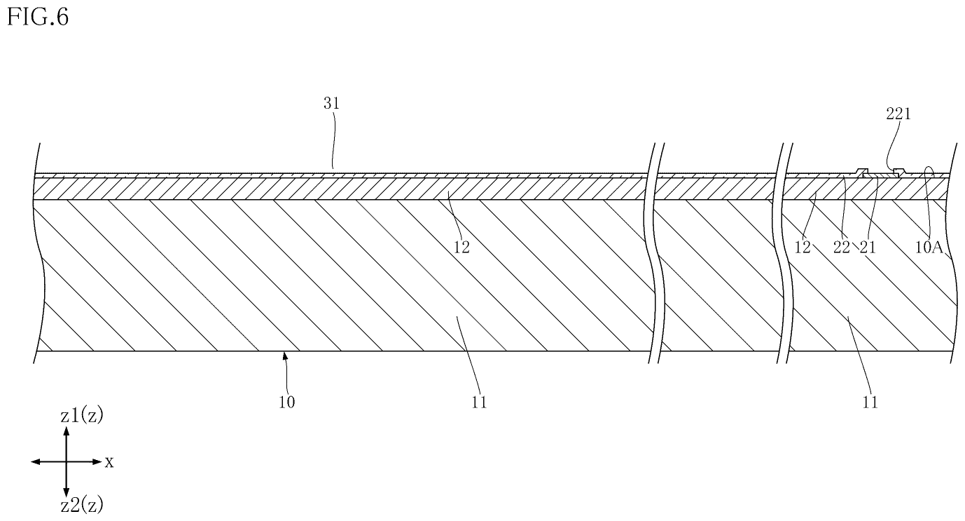

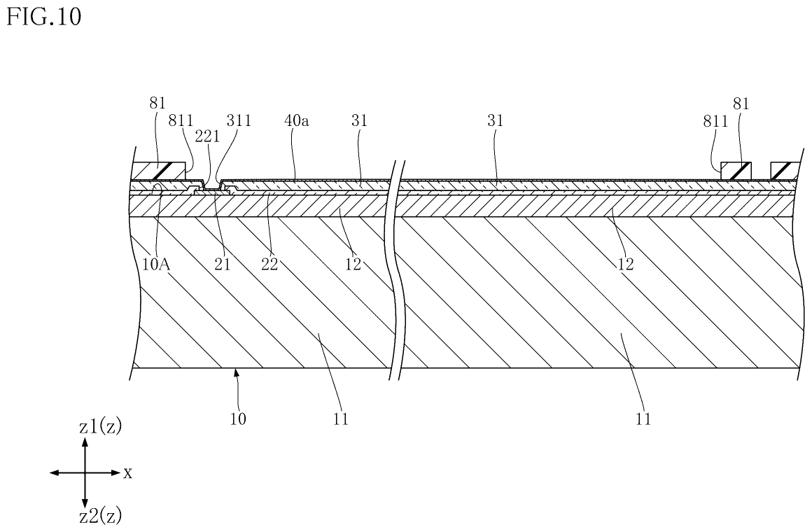

With reference to FIGS. 6 to 24, the following describes an example of a method for manufacturing a semiconductor device A10. FIGS. 6 to 24 are enlarged sectional views, each illustrating a step of the method for manufacturing a semiconductor device A10. FIGS. 6 to 9, 11 to 13, 15 to 17, 19, 21, and 23 each show a sectional view corresponding to FIG. 5. FIGS. 10, 14, 18, 20, 22, and 24 each show a sectional view corresponding to the sectional view shown in FIG. 4.

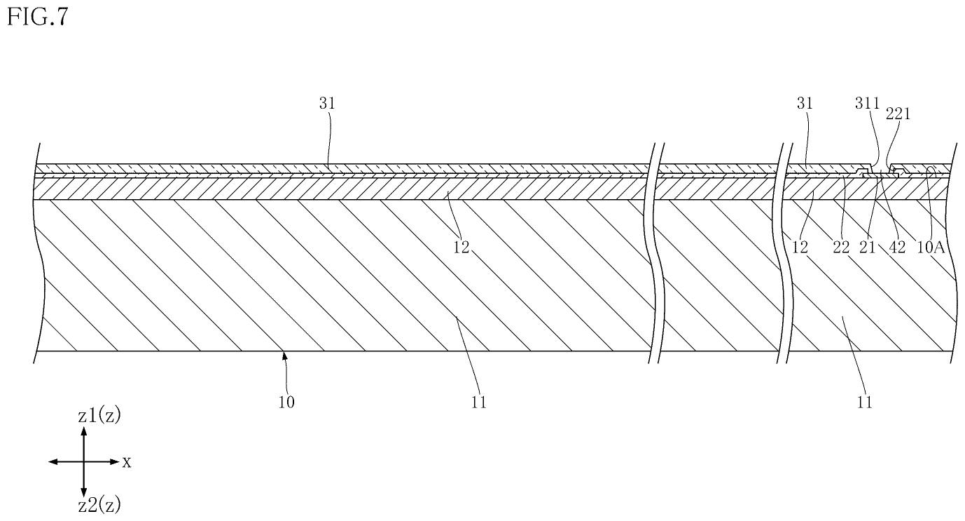

First, a semiconductor element 10 is prepared as shown in FIG. 6. The semiconductor element 10 at this stage is part of a silicon wafer. The semiconductor element 10 is provided with a plurality of electrodes 21 and a passivation film 22 on the z1 side in the thickness direction z. Subsequently, a first insulating film 31 is formed on the z1 side of the semiconductor element 10 in the thickness direction z as shown in FIG. 7. The process of forming the first insulating film 31 involves applying photosensitive polyimide to the passivation film 22 using, for example, spin coating, followed by lithographic patterning and hardening. As a result of the lithographic patterning, a plurality of first openings 311 are formed in the first insulating film 31. Each first opening 311 exposes a portion of an electrode 21. Note that the process for forming the first insulating film 31 can be changed as necessary, depending on the material used for the first insulating film 31. Note, in addition, that the first openings 311 shown in the figures are inclined (more specifically, each first opening 311 has an inner surface that is inclined) relative to the thickness direction z, but the shape of the first openings 311 is not limited to this. For example, depending on the process of forming the first openings 311, each first opening 311 may be formed in a shape that extends along the thickness direction z without inclination in the thickness direction z.

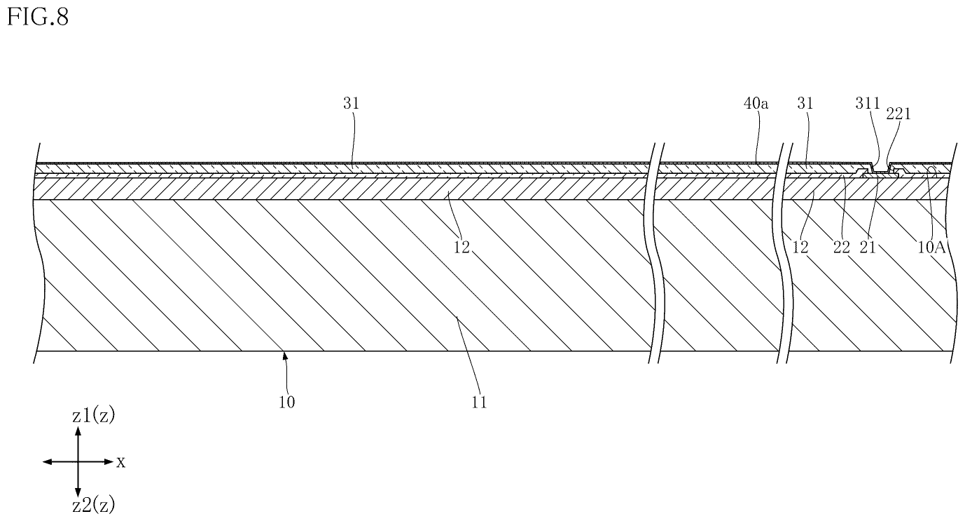

Subsequently, a first base layer 40a is formed as shown in FIG. 8. The first base layer 40a may be formed using spin coating. However, the method for forming the first base layer 40a is not limited to this. For example, sputtering may be used. In this step, the first base layer 40a is formed to cover the entire first insulating film 31, as well as the portions of the passivation film 22 and the electrodes 21 that are exposed through the first openings 311 in the first insulating film 31. In other words, the in-process semiconductor device A10 shown in FIG. 7 has an upper surface (the surface facing the z1 side in the thickness direction z) that is entirely covered with the first base layer 40a. The process of forming the first base layer 40a may involve forming a barrier layer containing titanium, for example, and then forming a seed layer containing copper.

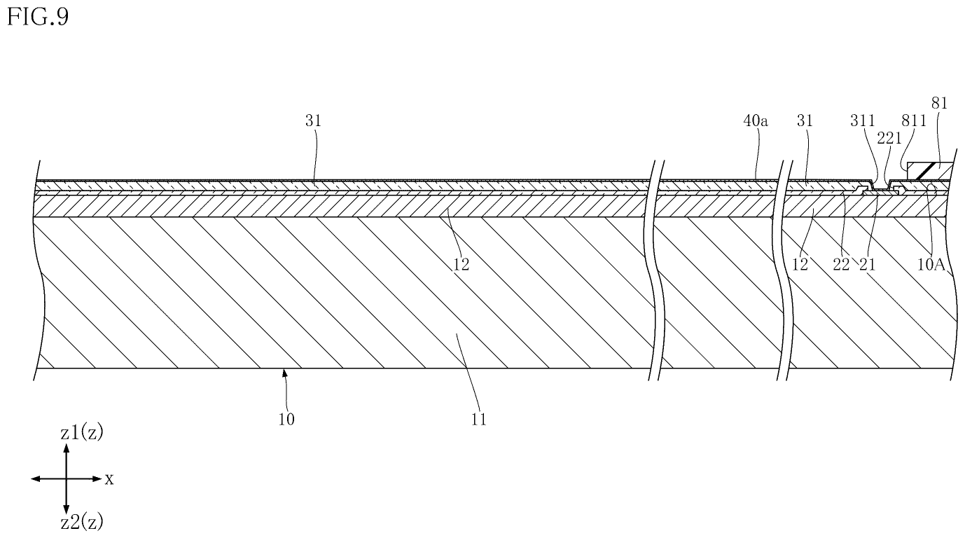

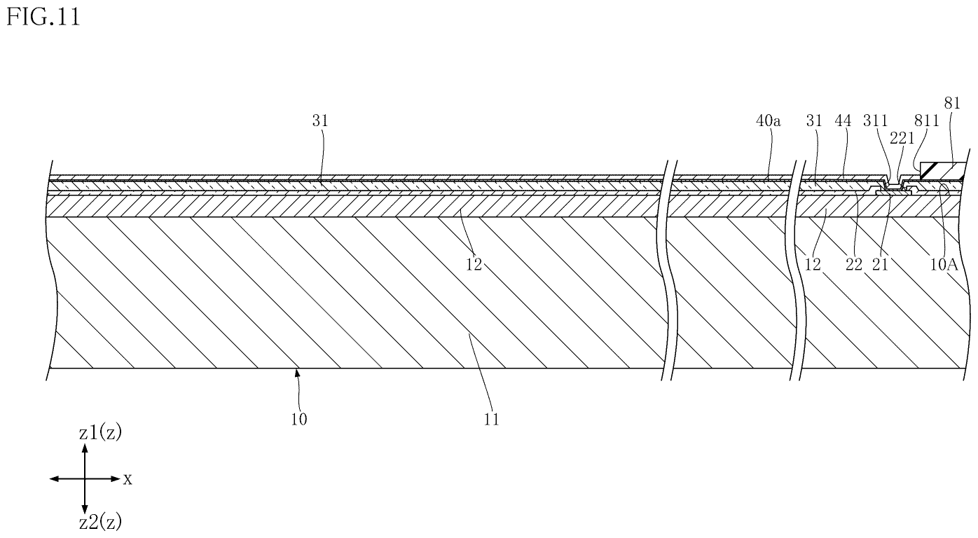

Subsequently, a first metal layer 44 is formed as shown in FIGS. 9 to 11. To form the first metal layer 44, a first resist 81 is applied to the first base layer 40a and then patterned using lithography as shown in FIGS. 9 and 10. As a result, a plurality of openings 811 are formed through the first resist 81 in the thickness direction z. Subsequently, electroplating is performed using the first base layer 40a as the conduction path, depositing the first metal layer 44 as shown in FIG. 11. The first metal layer 44 contains copper, for example. Through the above, a plurality of first metal layers 44 are formed in the respective openings 811. Each first metal layer 44 forms a first re-wiring 411 or a part of the second re-wiring 412.

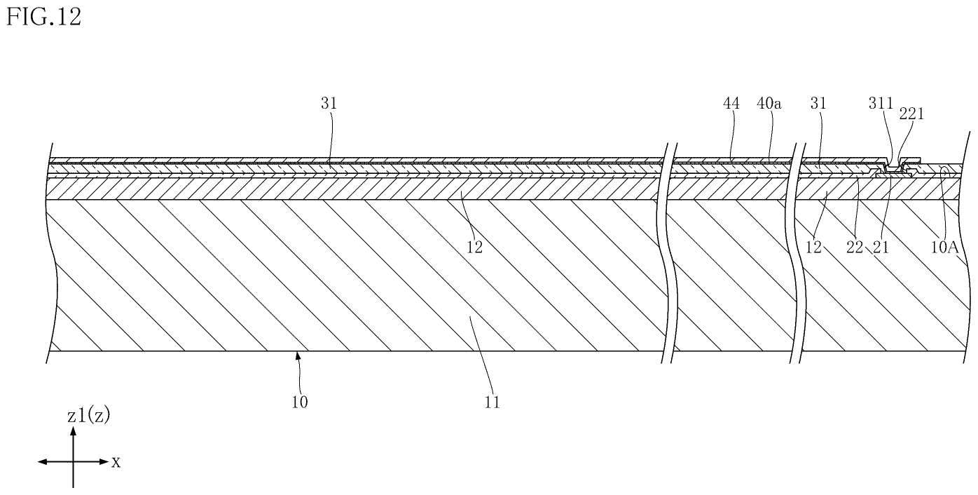

Subsequently, as shown in FIG. 12, the first resist 81 is removed, and then the portions of the first base layer 40a that are not covered with the first metal layer 44 are removed. The removal of the first base layer 40a may be performed using wet etching with a mixed solution of sulfuric acid (H₂SO₄) and hydrogen peroxide (H₂O₂), for example. As shown in FIG. 12, each first metal layer 44 is partly located inside the first opening 311, partly on the first insulating film 31, and partly on the electrode 21.

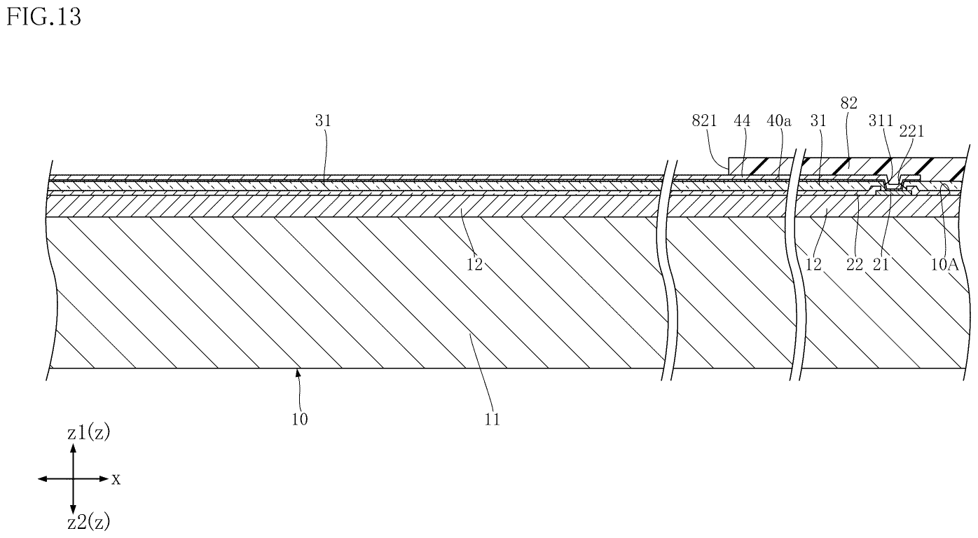

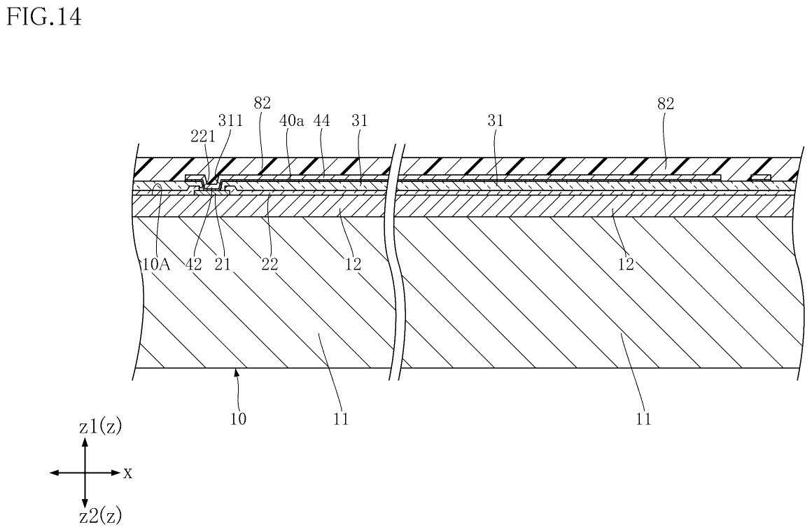

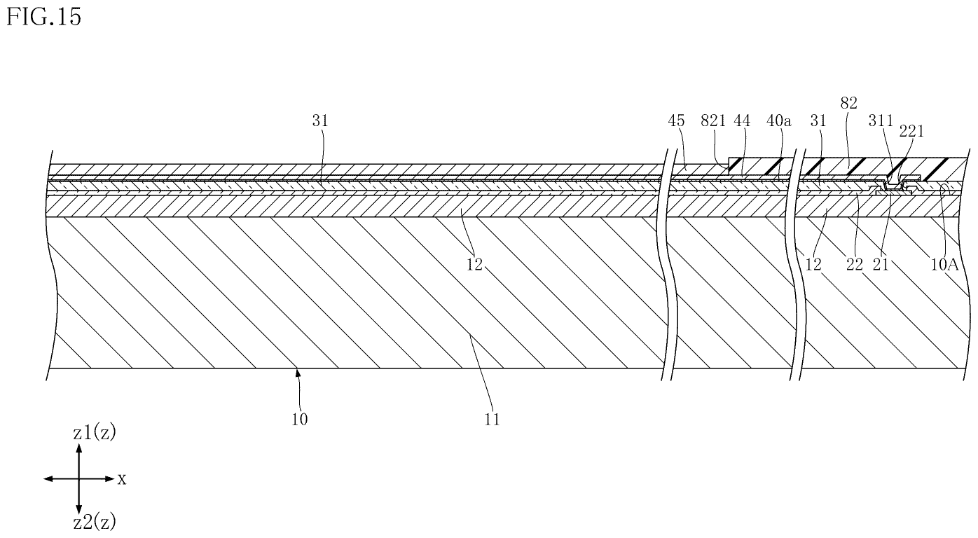

Subsequently, a second metal layer 45 is formed as shown in FIGS. 13 to 16. To form the second metal layer 45, a second resist 82 is applied to the first insulating film 31 and the first metal layer 44 and is then patterned using lithography as shown in FIGS. 13 and 14. As a result, an opening 821 is formed through the second resist 82 in the thickness direction z. In this state, a portion of a first metal layer 44 is exposed through the opening 821. Subsequently, electroplating is performed using the first metal layer 44 as the conduction path, depositing the second metal layer 45 as shown in FIG. 15. The second metal layer 45 contains copper, for example. In one example, the second metal layer 45 has the same composition as the first metal layer 44. Through the above, the second metal layer 45 is formed in the opening 821.

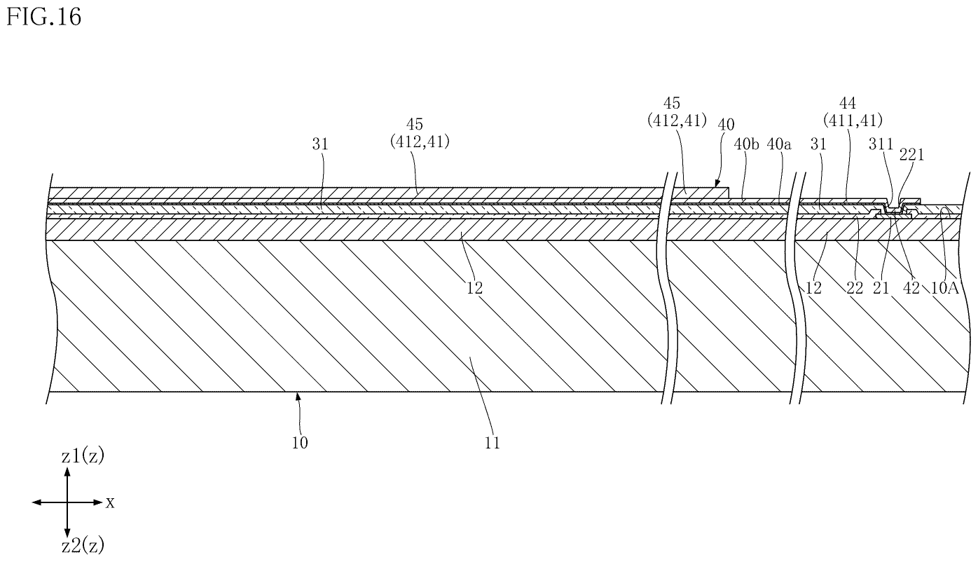

Subsequently, the second resist 82 is removed as shown in FIG. 16. In this state, as shown in FIGS. 15 and 16, the second metal layer 45 and the portion of the first metal layer 44 that overlaps with the second metal layer 45 in the thickness direction z together form the second re-wiring 412. Through the above, a plurality of re-wirings 40 are formed.

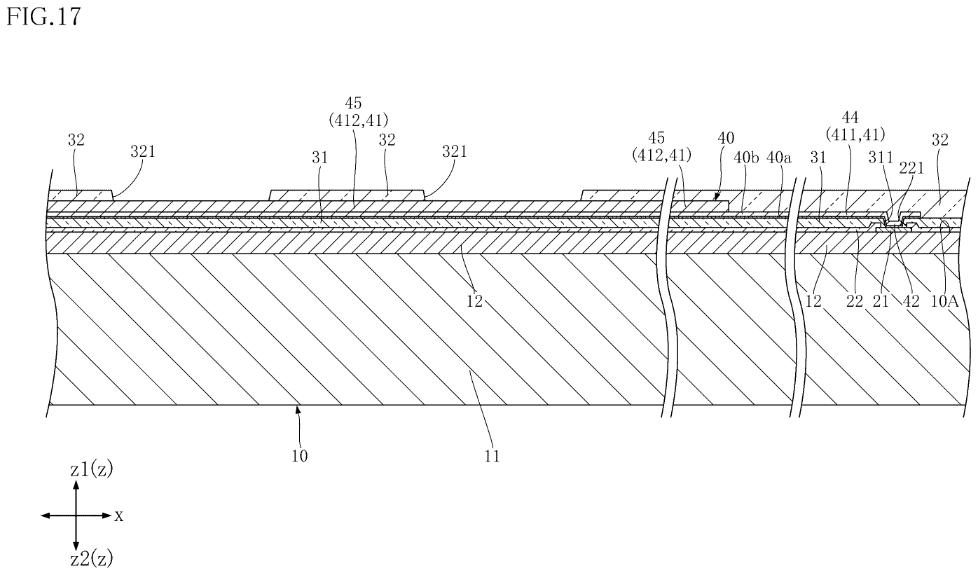

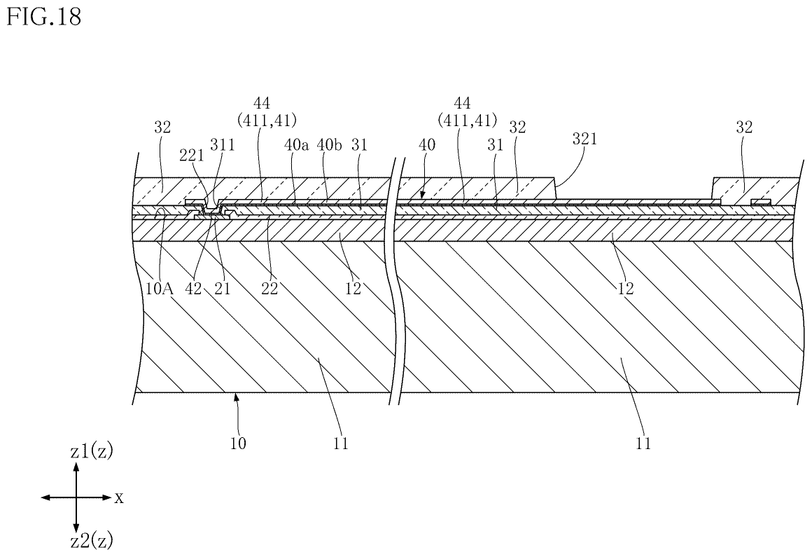

Subsequently, a second insulating film 32 is formed as shown in FIGS. 17 and 18. To form the second insulating film 32, a material containing photosensitive polyimide is applied to the re-wirings 40 and the portion of the first insulating film 31 that is not covered with the re-wirings 40, followed by lithographic patterning and hardening. As a result of the lithographic patterning, a plurality of second openings 321 are formed in the second insulating film 32. Each second opening 321 exposes a portion of a re-wiring 40 (a portion of a first metal layer 44 or a portion of a second metal layer 45). Note that the process for forming the second insulating film 32 can be changed as necessary, depending on the material used for the second insulating film 32. In addition, although the figures show the second openings 321 that are inclined relative to the thickness direction z, this is a non-limiting example. For example, depending on the process used for forming the second openings 321, each second opening 321 may be formed in a shape that extends along the thickness direction z without inclination.

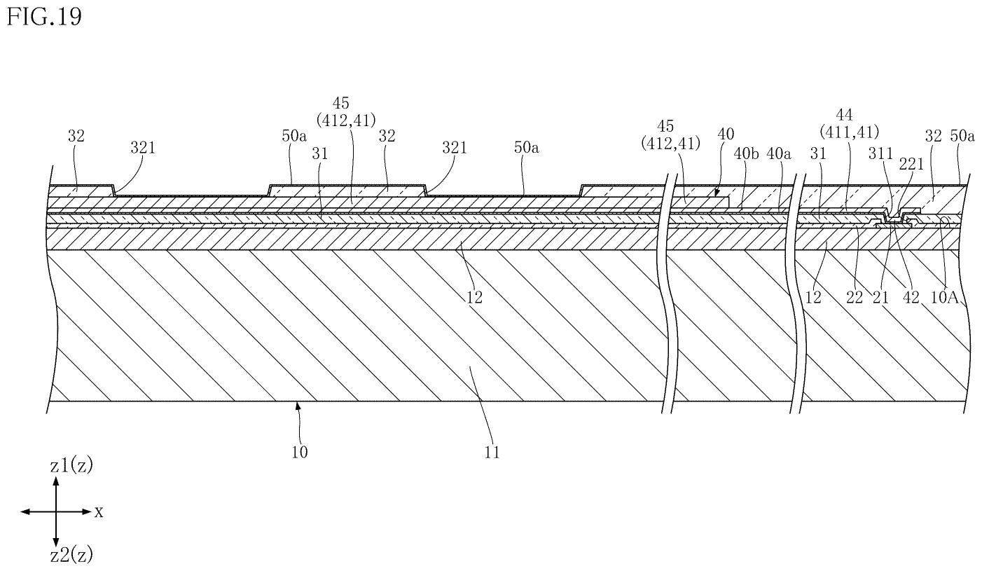

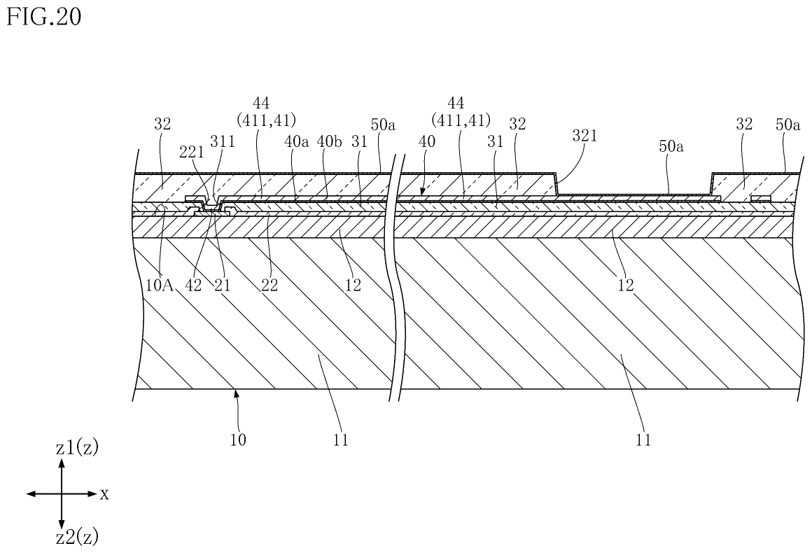

Subsequently, a second base layer 50a is formed as shown in FIGS. 19 and 20. The second base layer 50a may be formed using sputtering, but this is a non-limiting example. In this step, the second base layer 50a is formed to cover the entire second insulating film 32, as well as the portions of the re-wirings 40 (the portions of the first metal layer 44 and of the second metal layer 45) that are exposed through the second openings 321 in the second insulating film 32. In other words, the in-process semiconductor device A10 shown in FIGS. 17 and 18 has an upper surface (the surface facing the z1 side in the thickness direction z) that is entirely covered with the second base layer 50a. The process of forming the second base layer 50a may involve forming a barrier layer containing titanium, for example, and then forming a seed layer containing copper.

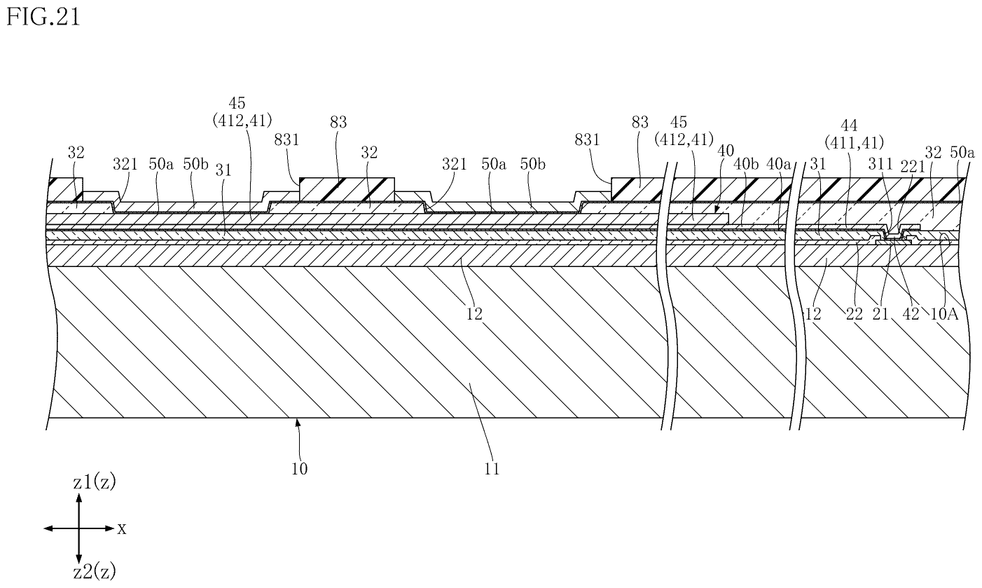

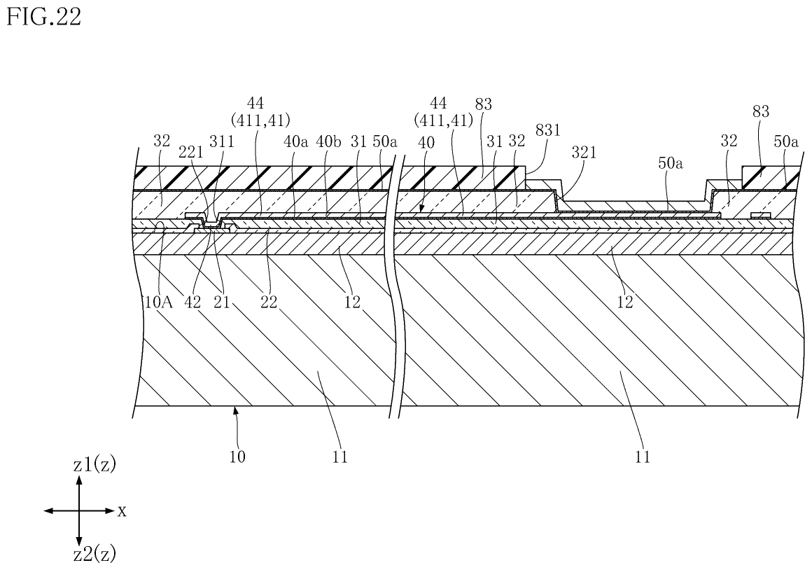

Subsequently, a second conductive layer 50b is formed as shown in FIGS. 21 to 24. To form the second conductive layer 50b, a third resist 83 is applied to the second base layer 50a as shown in FIGS. 21 and 22, and is then patterned using lithography. As a result, a plurality of openings 831 are formed through the third resist 83 in the thickness direction z. Subsequently, electroplating is performed using the second base layer 50a as the conduction path, depositing the second conductive layer 50b. The second conductive layer 50b contains copper, for example. Through the above, a plurality of second conductive layers 50b are formed within the openings 831.

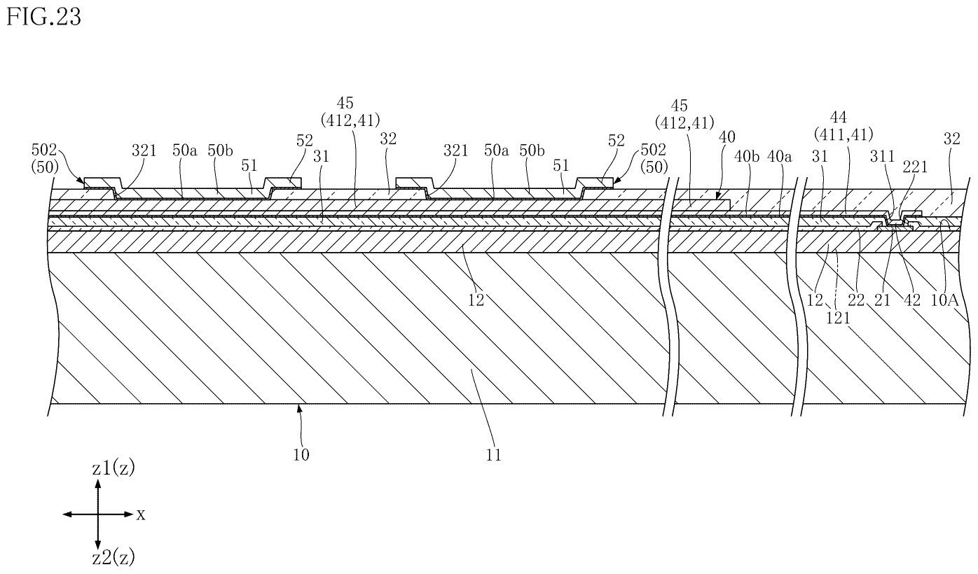

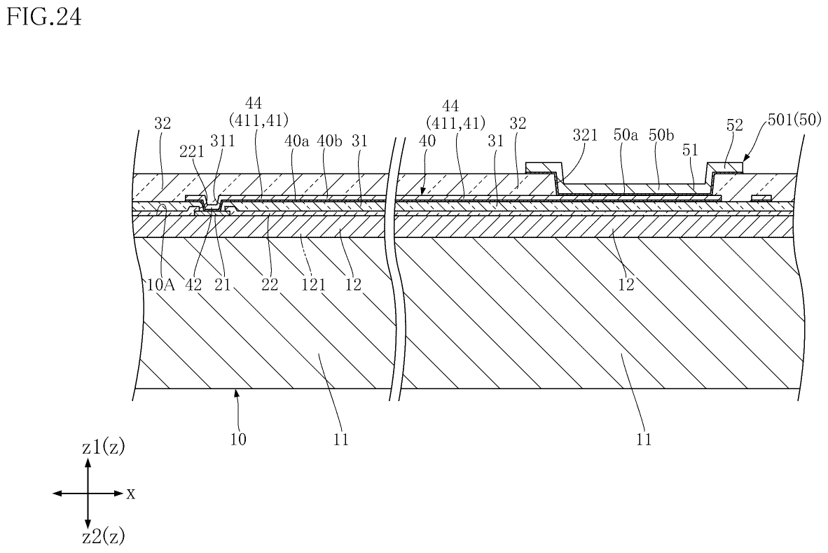

Subsequently, as shown in FIGS. 23 and 24, the third resist 83 is removed, and then the portions of the second base layer 50a that are not covered with the second conductive layers 50b are removed. The removal of the second base layer 50a may be performed using wet etching with a mixed solution of sulfuric acid and hydrogen peroxide, for example. Through the above, a plurality of terminals 50 (a plurality of first terminals 501 and a plurality of second terminals 502) are formed.

Subsequently, a plurality of conductive bonding layers 60 are formed. To form the conductive bonding layers 60, a material containing solder is placed on the respective terminals 50, reflowed, and then allowed to harden. Through the above, the plurality of conductive bonding layers 60 are formed on the respective terminals 50.

Finally, the semiconductor element 10, which at this stage is still part of a silicon wafer, is separated into an individual chip using blade dicing. Through the steps described above, the semiconductor device A10 is manufactured. Note, however, that the method for manufacturing the semiconductor device A10 described above is a non-limiting example.

To prepare for use, the semiconductor device A10 is surface-mounted on a circuit board (not illustrated), for example. The terminals 50 of the semiconductor device A10 are electrically bonded to the conductive parts of the circuit board individually via the conductive bonding layers 60. As a result, the electrodes 21 of the semiconductor device A10 are electrically connected to the conductive parts of the circuit board.

The following describes the effects of the semiconductor device A10.

The semiconductor device A10 includes a semiconductor element 10, an electrode 21, a re-wiring 40, and a terminal 50. The electrode 21 is located on the z1 side in the thickness direction z of the semiconductor element 10. The re-wiring 40 is located on the z1 side in the thickness direction z with respect to the electrode 21 and is electrically connected to the electrode 21. The terminal 50 is located on the z1 side in the thickness direction z with respect to the re-wiring 40 and is electrically connected to the re-wiring 40. The re-wiring 40 forms a conduction path connecting the semiconductor element 10 and the terminal 50, which will be electrically bonded to a circuit board, for example. The re-wiring 40 includes a first re-wiring 411 and the second re-wiring 412. The dimension t2 of the second re-wiring 412 in the thickness direction z is greater than the dimension t1 of the first re-wiring 411 in the thickness direction z. That is, the re-wiring 40 forming a conduction path connecting the semiconductor element 10 to an external component (e.g., a circuit board) includes the second re-wiring 412 having lower resistance than the first re-wiring 411. Since the re-wiring 40 for carrying electric current includes the second re-wiring 412 having a relatively large dimension t2 in the thickness direction z, the semiconductor device A10 achieves reduced resistance even when a large electric current is fed to the semiconductor device A10. Note, in addition, that the second re-wiring 412 is applied only to a specific portion of the re-wiring 40 where reducing resistance is necessary. This allows the first re-wiring 411, which is not required to have lower resistance, to have the relatively small dimension t1 in the thickness direction z. Thus, the re-wiring 40 is well-suited for a fine wiring layout as shown in FIGS. 1 to 3.

The dimension t2 of the second re-wiring 412 in the thickness direction z is at least 150% of the dimension t1 of the first re-wiring 411 in the thickness direction z. This configuration ensures that the second re-wiring 412 has an appropriately lower resistance than that of the first re-wiring 411. Preferably, the dimension t2 of the second re-wiring 412 in the thickness direction z is at least 150% and at most 1000% of the dimension t1 of the first re-wiring 411 in the thickness direction z. This configuration prevents the overall dimension of the semiconductor device A10 in the thickness direction z from becoming extremely large.

The semiconductor element 10 includes a first circuit 121 and a second circuit 122. The first re-wiring 411 is electrically connected to the first circuit 121, and the second re-wiring 412 is electrically connected to the second circuit 122. The second circuit 122 is driven by the first circuit 121. The second circuit 122 may be a switching circuit. Thus, the second re-wiring 412, which is electrically connected to the second circuit 122, may conduct a large electric current. The configuration described above effectively reduces the resistance of the second re-wiring 412, which may conduct a large electric current.

The terminal 50 includes a first terminal 501 electrically connected to the first re-wiring 411, and a second terminal 502 electrically connected to the second re-wiring 412. The semiconductor device A10 includes a plurality of second terminals 502 connected to the second re-wiring 412. With this configuration, the second re-wiring 412, which has a relatively large dimension t2 in the thickness direction z, is provided over a wide area as viewed in the thickness direction z. This configuration more effectively reduces the resistance of the second re-wiring 412.

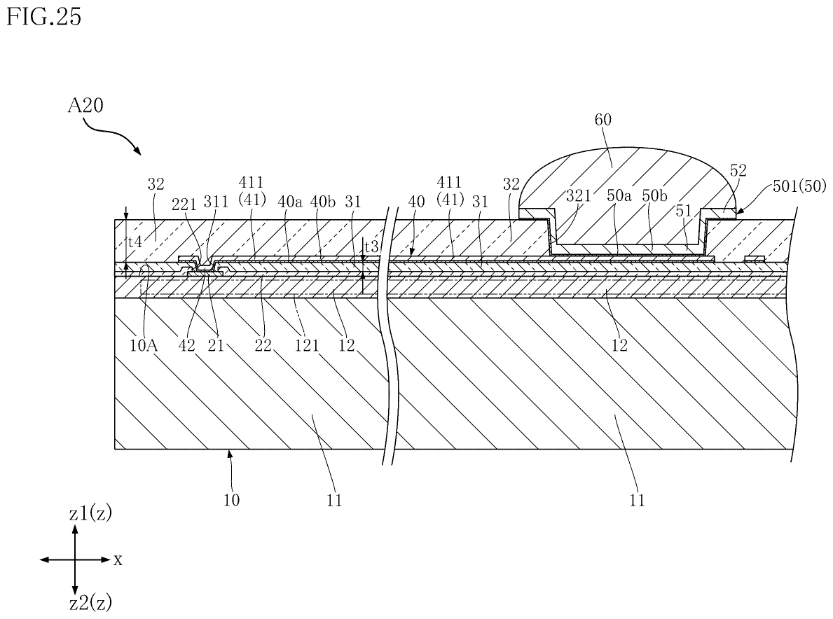

FIGS. 25 to 29 show semiconductor devices according to other embodiments of the present disclosure. In these figures, elements that are identical or similar to those of the embodiment described above are indicated by the same reference numerals, and redundant descriptions are omitted. In addition, configurations of elements and components in the embodiments may be combined in any manner, provided that no technical inconsistencies arise.

### Second Embodiment

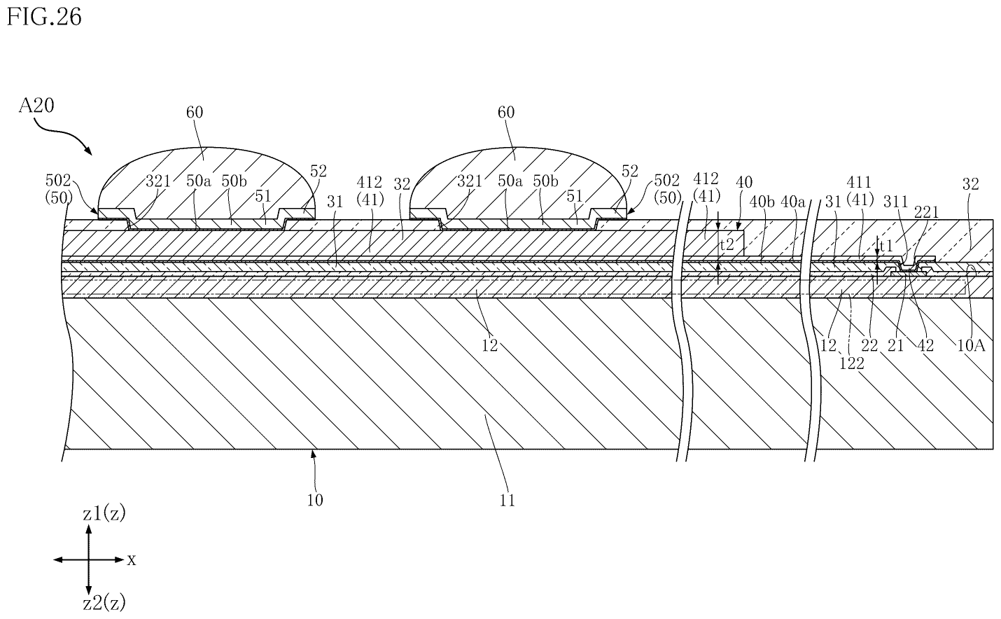

FIGS. 25 and 26 show a semiconductor device A20 according to a second embodiment of the present disclosure. FIGS. 25 and FIG. 26 are each a partially enlarged sectional view of the semiconductor device A20. FIG. 25 shows a sectional view corresponding to FIG. 4, and FIG. 26 to FIG. 5.

In the semiconductor device A20, the dimension t2 of the second re-wiring 412 in the thickness direction z is greater than that in the semiconductor device A10 of the first embodiment. To give specific examples of the respective dimensions t1 and t2 of the semiconductor device A20, the dimension t1 of the first re-wirings 411 in the thickness direction z is about 5 μm, and the dimension t2 of the second re-wiring 412 in the thickness direction z is about 20 to 50 μm. Note, however, that the dimensions t1 and t2 of the first re-wirings 411 and the second re-wiring 412 are not limited to these examples. In the semiconductor device A20, the dimension t4 of the second insulating film 32 in the thickness direction z is also greater than that in the semiconductor device A10 to cope with that the dimension t2 of the second re-wiring 412 in the thickness direction z is greater.

Similarly to the manufacture of the semiconductor device A10 described with reference to FIGS. 13 to 16, the second metal layer 45 of the semiconductor device A20 is formed by electroplating but to a greater thickness.

In the semiconductor device A20, the dimension t2 of the second re-wiring 412 in the thickness direction z is greater than the dimension t1 of the first re-wirings 411 in the thickness direction z. That is, the re-wiring 40 forming a conduction path connecting the semiconductor element 10 to an external component (e.g., a circuit board) includes the second re-wiring 412 having lower resistance than the first re-wirings 411. Since the re-wiring 40 for carrying electric current includes the second re-wiring 412 having a relatively large dimension t2 in the thickness direction z, the semiconductor device A20 achieves reduced resistance even when a large electric current is fed to the semiconductor device A20. Note, in addition, that the second re-wiring 412 is applied only to a specific portion of the re-wirings 40 where reducing resistance is necessary. This allows the first re-wirings 411, which are not required to have lower resistance, to have the relatively small dimension t1 in the thickness direction z. Thus, the re-wirings 40 are well-suited for a fine wiring layout.

In the semiconductor device A20, the second re-wiring 412 has a greater dimension t2 in the thickness direction z. This achieves the further reduction of the resistance of the second re-wiring 412. Additionally, the semiconductor device A20 has a configuration in common with the semiconductor device A10, thereby achieving the same effect as the semiconductor device A10.

### Third Embodiment

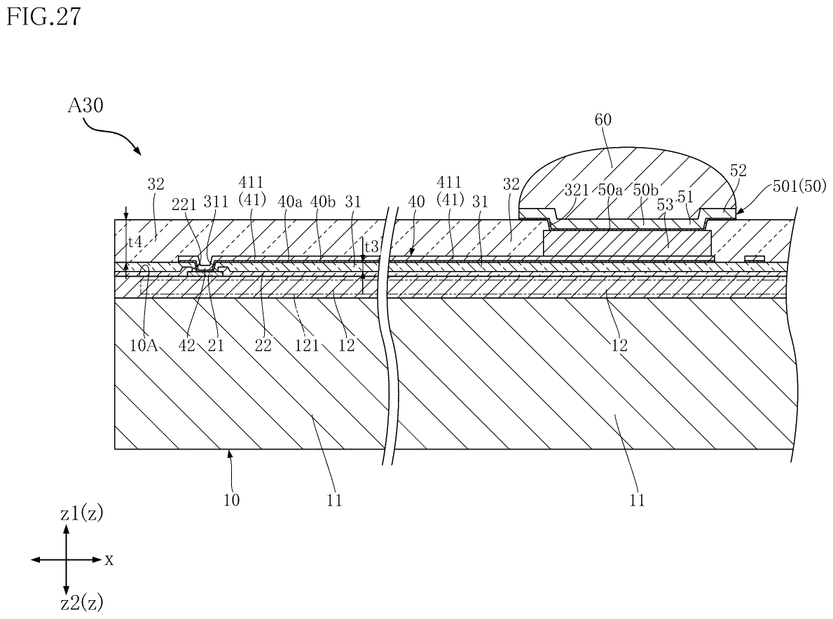

FIG. 27 shows a semiconductor device A30 according to a third embodiment of the present disclosure. FIG. 27 is a partially enlarged sectional view of the semiconductor device A30 and corresponds to FIG. 4.

The semiconductor device A30 differs from the semiconductor device A20 in the configuration of a first terminals 501. In the semiconductor device A30, the first terminal 501 includes a base portion 53 in addition to the first portion 51 and the second portion 52. The base portion 53 is located between a re-wiring 40 and the first portion 51 and is connected to both a first re-wiring 411 and the first portion 51. As viewed in thickness direction z, the base portion 53 overlaps with the entire first portion 51. The base portion 53 consists of the second metal layer 45 formed as described in the manufacture of the semiconductor device A10 with reference to FIGS. 13 to 16. The semiconductor device A30 has a configuration in common with the semiconductor device A10, thereby achieving the same effect as the semiconductor device A10.

### Fourth Embodiment

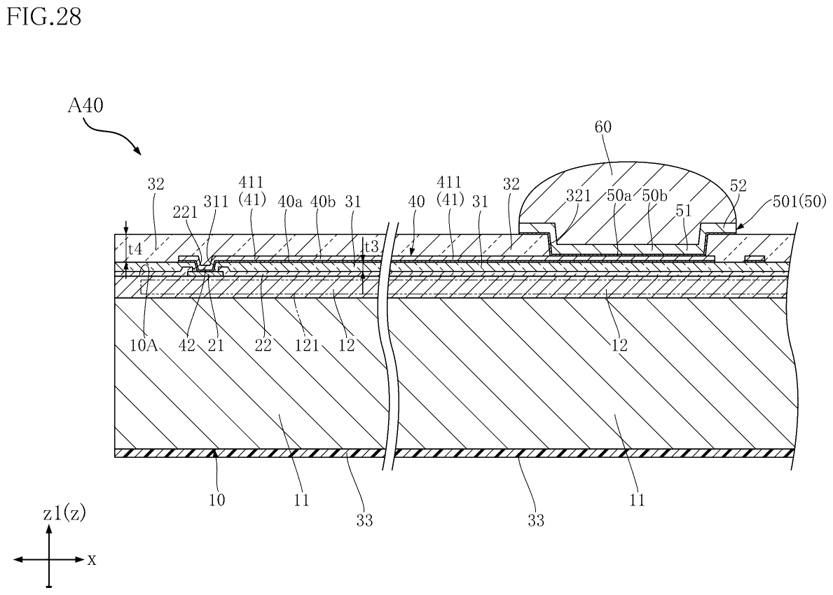

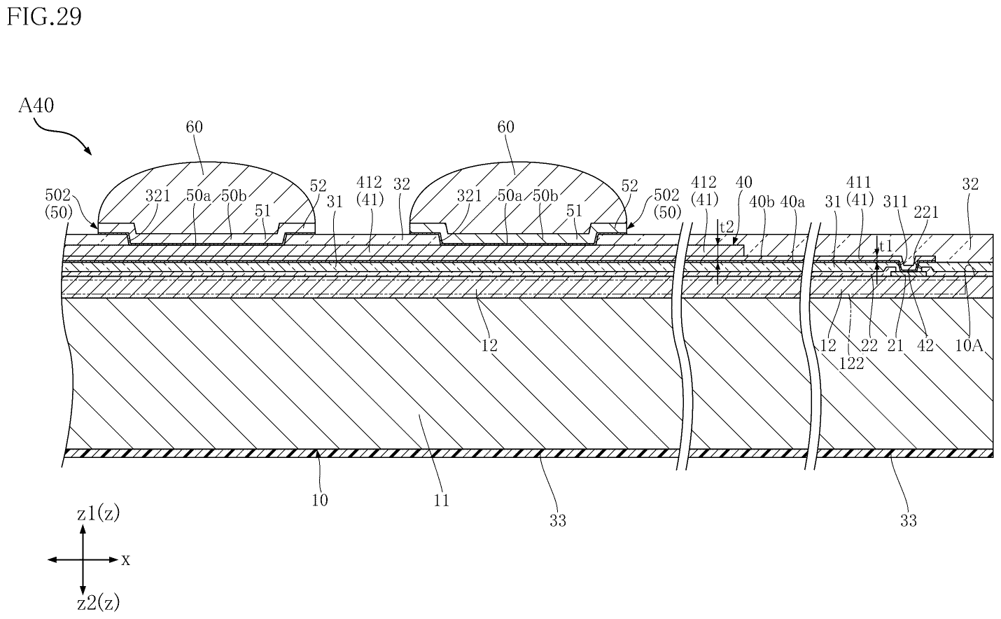

FIGS. 28 and 29 show a semiconductor device A40 according to a fourth embodiment of the present disclosure. FIGS. 28 and FIG. 29 are each a partially enlarged sectional view of the semiconductor device A40. FIG. 28 shows a sectional view corresponding to FIG. 4, and FIG. 29 to FIG. 5.

The semiconductor device A40 differs from the semiconductor device A10 by the addition of a third insulating film 33.

The third insulating film 33 is located on the opposite side of the semiconductor element 10 from the plurality of electrodes 21 in the thickness direction z. The third insulating film 33 covers the semiconductor element 10 from the z2 side in the thickness direction z. The third insulating film 33 is made of an insulating resin sheet, for example.

In the semiconductor device A40, the dimension t2 of the second re-wiring 412 in the thickness direction z is greater than the dimension t1 of the first re-wirings 411 in the thickness direction z. That is, the re-wiring 40 forming a conduction path connecting the semiconductor element 10 to an external component (e.g., a circuit board) includes the second re-wiring 412 having lower resistance than the first re-wirings 411. Since the re-wiring 40 for carrying electric current includes the second re-wiring 412 having a relatively large dimension t2 in the thickness direction z, the semiconductor device A40 achieves reduced resistance even when a large electric current is fed to the semiconductor device A40. Note, in addition, that the second re-wiring 412 is applied only to a specific portion of the re-wirings 40 where reducing resistance is necessary. This allows the first re-wirings 411, which are not required to have lower resistance, to have the relatively small dimension t1 in the thickness direction z. Thus, the re-wirings 40 are well-suited for a fine wiring layout.

The semiconductor device A40 additionally includes the third insulating film 33. The third insulating film 33 covers the semiconductor element 10 from the z2 side in the thickness direction z. The third insulating film 33 appropriately protects the semiconductor element 10 (the semiconductor device A40). Additionally, the semiconductor device A40 has a configuration in common with the semiconductor device A10, thereby achieving the same effect as the semiconductor device A10.

The semiconductor devices according to the present disclosure are not limited to the embodiments described above. The specific configuration of each part of a semiconductor device according to the present disclosure may suitably be designed and changed in various manners. Although the embodiments described above are directed to the semiconductor devices A10 to A40 each formed using WL-CSP, the present disclosure is not limited to these. For example, the semiconductor devices according to the present disclosure may be resin packaged devices that is sealed with mold resin.

The present disclosure includes the configurations described in the following clauses.

### Clause 1

A semiconductor device (A10) comprising:
a semiconductor element (10);
an electrode (21) located on a first side (z1 side) in a thickness direction (z) of the semiconductor element (10);
a re-wiring (40) located on the first side (z1 side) in the thickness direction with respect to the electrode (21) and electrically connected to the electrode (21); and
a terminal (50) located on the first side (z1 side) in the thickness direction with respect to the re-wiring (40) and electrically connected to the re-wiring (40),
wherein the re-wiring (40) includes a first re-wiring (411) and a second re-wiring (412), and
a dimension (t2) of the second re-wiring (412) in the thickness direction (z) is greater than a dimension (t1) of the first re-wiring (411) in the thickness direction (z).

### Clause 2

The semiconductor device (A10) according to Clause 1, wherein the dimension (t2) of the second re-wiring (412) in the thickness direction (z) is at least 150% of the dimension (t1) of the first re-wiring (411) in the thickness direction (z).

### Clause 3

The semiconductor device (A10, A20) according to Clause 1, wherein the dimension (t2) of the second re-wiring (412) in the thickness direction (z) is at least 150% and at most 1000% of the dimension (t1) of the first re-wiring (411) in the thickness direction (z).

### Clause 4

The semiconductor device (A10) according to any one of Clauses 1 to 3, wherein the semiconductor element (10) includes a first circuit (121), and a second circuit (122) driven by the first circuit (122),
the first re-wiring (411) is electrically connected to the first circuit (121), and the second re-wiring (412) is electrically connected to the second circuit (122).

### Clause 5

The semiconductor device (A10) according to any one of Clauses 1 to 4, wherein the terminal (50) includes a first terminal (501) electrically connected to the first re-wiring (411), and a second terminal (502) electrically connected to the second re-wiring (412).

### Clause 6

The semiconductor device (A10) according to Clause 5, wherein a plurality of the second terminals (502) are connected to the second re-wiring (412).

### Clause 7

The semiconductor device (A10) according to any one of Clauses 1 to 6, further comprising a conductive bonding layer (60) located on the first side (z1 side) in the thickness direction (z) with respect to the terminal (50) and electrically connected to the terminal (50).

### Clause 8

The semiconductor device (A10) according to any one of Clauses 1 to 7, further comprising a first insulating film (31) located between the semiconductor element (10) and the re-wiring (40) in the thickness direction (z),
wherein the first insulating film (31) is provided with a first opening (311) extending therethrough in the thickness direction (z) and exposing the electrode (21), and
a portion of the re-wiring (40) is received within the first opening (311).

### Clause 9

The semiconductor device (A10) according to Clause 8, further comprising a second insulating film (32) located on the first side (z1 side) in the thickness direction (z) with respect to the first insulating film (31) and covering the re-wiring (40),
wherein the second insulating film (32) is provided with a second opening (321) extending therethrough in the thickness direction (z) and exposing the re-wiring (40), and
a portion of the terminal (50) is received within the second opening (321).

### Clause 10

The semiconductor device (A10) according to Clause 9, wherein a dimension (t4) of the second insulating film (32) in the thickness direction (z) is greater than a dimension (t3) of the first insulating film (31) in the thickness direction (z).

### Clause 11

The semiconductor device according to Clause 9 or 10, wherein the terminal (50) includes a first portion (51) received within the second opening (321), and a second portion (52) protruding beyond the second opening (321), and
as viewed in the thickness direction (z), the second portion (52) is located outside the second opening (321).

### Clause 12

The semiconductor device (A10) according to any one of Clauses 9 to 11, wherein the re-wiring (40) includes a first base layer (40a) in contact with the electrode (21) and the first insulating film (31), and a first conductive layer (40b) stacked on the first base layer (40a).

### Clause 13

The semiconductor device (A10) according to Clause 12, wherein the terminal (50) includes a second base layer (50a) in contact with the re-wiring (40) and the second insulating film (32), and a second conductive layer (50b) stacked on the second base layer (50b).

### Clause 14

The semiconductor device (A40) according to any one of Clauses 1 to 13, further comprising a third insulating film (33) covering the semiconductor element (10) from a second side (z2 side) in the thickness direction (z).

### Clause 15

A method for manufacturing a semiconductor device (A10), the method comprising:
preparing a semiconductor element (10) provided with an electrode (21) on a first side (z1 side) in a thickness direction (z);
forming a first insulating film (31) on the first side (z1 side) of the semiconductor element (10) in the thickness direction (z), the first insulating film (31) including a first opening (311) that exposes the electrode (21);
forming a first metal layer (44) on the electrode (21) and a portion of the first insulating film (31), wherein a portion of the first metal layer is received within the first opening (311) in the first insulating film (31);
forming a second metal layer (45) on a portion of the first metal layer (44);
forming a second insulating film (32) on the first side (z1 side) of the first metal layer (44) and the second metal layer (45) in the thickness direction (z), the second insulating film (32) including a second opening (321) that exposes a portion of the first metal layer (44) and a portion of the second metal layer (45); and
forming a terminal (50) on a portion of the first metal layer (44), a portion of the second metal layer (45), and a portion of the second insulating film (32), wherein a portion of the terminal (50) is received within the second opening (321) in the second insulating film (32).

### Clause 16

The semiconductor device (A30) according to Clause 11, wherein the terminal (50) includes a base portion (53) located between the re-wiring (40) and the first portion (51) in the thickness direction (z), and
the base portion (53) is connected to both the first re-wiring (411) and the first portion (51).

### REFERENCE NUMERALS

A10, A20, A30, A40: semiconductor device 10: semiconductor element 10A: obverse surface 11: semiconductor substrate 12: semiconductor layer 121: first circuit 122: second circuit 21: electrode 22: passivation film 221: opening 31: first insulating film 311: first opening 32: second insulating film 321: second opening 33: third insulating film 40: re-wiring 40a: first base layer 40b: first conductive layer 41: main portion 411: first re-wiring 412: second re-wiring 42: contact portion 44: first metal layer 45: second metal layer 50: terminal 50a: second base layer 50b: second conductive layer 501: first terminal 502: second terminal 51: first portion 52: second portion 53: base portion 60: conductive bonding layer 81: first resist 82: second resist 83: third resist 811, 821, 831: opening t1, t2, t3, t4: dimension x: first direction y: second direction z: thickness direction

1. A semiconductor device comprising:
a semiconductor element;
an electrode located on a first side in a thickness direction of the semiconductor element;
a re-wiring located on the first side in the thickness direction with respect to the electrode and electrically connected to the electrode; and
a terminal located on the first side in the thickness direction with respect to the re-wiring and electrically connected to the re-wiring,
wherein the re-wiring includes a first re-wiring and a second re-wiring, and
a dimension of the second re-wiring in the thickness direction is greater than a dimension of the first re-wiring in the thickness direction.

2. The semiconductor device according to claim 1, wherein the dimension of the second re-wiring in the thickness direction is at least 150% of the dimension of the first re-wiring in the thickness direction.

3. The semiconductor device according to claim 1, wherein the dimension of the second re-wiring in the thickness direction is at least 150% and at most 1000% of the dimension of the first re-wiring in the thickness direction.

4. The semiconductor device according to claim 1, wherein the semiconductor element includes a first circuit, and a second circuit driven by the first circuit,
the first re-wiring is electrically connected to the first circuit, and the second re-wiring is electrically connected to the second circuit.

5. The semiconductor device according to claim 1, wherein the terminal includes a first terminal electrically connected to the first re-wiring, and a second terminal electrically connected to the second re-wiring.

6. The semiconductor device according to claim 5, further comprising an additional second terminal connected to the second re-wiring.

7. The semiconductor device according to claim 1, further comprising a conductive bonding layer located on the first side in the thickness direction with respect to the terminal and electrically connected to the terminal.

8. The semiconductor device according to claim 1, further comprising a first insulating film located between the semiconductor element and the re-wiring in the thickness direction,
wherein the first insulating film is provided with a first opening extending therethrough in the thickness direction and exposing the electrode, and
a portion of the re-wiring is received within the first opening.

9. The semiconductor device according to claim 8, further comprising a second insulating film located on the first side in the thickness direction with respect to the first insulating film and covering the re-wiring,
wherein the second insulating film is provided with a second opening extending therethrough in the thickness direction and exposing the re-wiring, and
a portion of the terminal is received within the second opening.

10. The semiconductor device according to claim 9, wherein a dimension of the second insulating film in the thickness direction is greater than a dimension of the first insulating film in the thickness direction.

11. The semiconductor device according to claim 9, wherein the terminal includes a first portion received within the second opening, and a second portion protruding beyond the second opening, and
as viewed in the thickness direction, the second portion extends outside beyond the second opening.

12. The semiconductor device according to claim 9, wherein the re-wiring includes a first base layer in contact with the electrode and the first insulating film, and a first conductive layer stacked on the first base layer.

13. The semiconductor device according to claim 12, wherein the terminal includes a second base layer in contact with the re-wiring and the second insulating film, and a second conductive layer stacked on the second base layer.

14. The semiconductor device according to claim 1, further comprising a third insulating film covering the semiconductor element from a second side in the thickness direction.

15. A method for manufacturing a semiconductor device, the method comprising:
preparing a semiconductor element provided with an electrode on a first side in a thickness direction;
forming a first insulating film on the first side in the thickness direction of the semiconductor element, the first insulating film including a first opening that exposes the electrode;
forming a first metal layer on the electrode and a portion of the first insulating film in a manner such that a portion of the first metal layer is received within the first opening in the first insulating film;
forming a second metal layer on a portion of the first metal layer;
forming a second insulating film on the first side in the thickness direction of the first metal layer and the second metal layer in a manner such that the second insulating film includes a second opening that exposes a portion of the first metal layer or a portion of the second metal layer; and
forming a terminal on a portion of the first metal layer, a portion of the second metal layer, or a portion of the second insulating film in a manner such that a portion of the terminal is received within the second opening in the second insulating film.
